(19) United States
(12) Patent Application Publication
(10) Pub. No.: US 2017/0110299 A1
(43) Pub. Date: Apr. 20, 2017

(54) SPUTTERING APPARATUS

(71) Applicant: Samsung Display Co., Ltd., Yongin-si (KR)

(72) Inventors: Chang Oh JEONG, Suwon-si (KR); Hyun Eok SHIN, Gwacheon-si (KR); Hyun Ju KANG, Yongin-si (KR); Joon Yong PARK, Gunpo-si (KR); Sang Woo SOHN, Yongin-si (KR); Sang Won SHIN, Yongin-si (KR); Dong Hee LEE, Hwaseong-si (KR)

(21) Appl. No.: 15/238,377

(22) Filed: Aug. 16, 2016

(30) Foreign Application Priority Data
Oct. 14, 2015 (KR) 10-2015-0143554

(51) Int. Cl. H01J 37/34; C23C 14/34

(52) U.S. Cl. CPC H01J 37/3423; H01J 37/3426; C23C 14/3407; C23C 14/3464; H01J 2237/332

(57) ABSTRACT

A sputtering apparatus includes a chamber, a target section disposed in the chamber, and a stage facing the target section. The target section includes a first target having a first diameter and a second target having a second diameter different from the first diameter. The first target and the second target each extend in a longitudinal direction and have a cylindrical shape, and the first and second diameters are respectively measured along a cross-section of corresponding first and second targets taken along a direction perpendicular to the longitudinal direction.

### CROSS-REFERENCE TO RELATED APPLICATION

This application claims priority from and the benefit of Korean Patent Application No. 10-2015-0143554 filed on Oct. 14, 2015, which is hereby incorporated by reference for all purposes as if fully set forth herein.

### BACKGROUND

Field

Exemplary embodiments relate to a sputtering apparatus.

Discussion of the Background

Display devices have become increasingly important along with the development of multimedia. As such, various types of display devices such as a liquid crystal display (LCD) and an organic light emitting display (OLED) are being used.

Such display devices include thin film layers formed on an insulating substrate. A method of forming a thin film layer may be broadly classified into a chemical vapor deposition (CVD) and a physical vapor deposition (PVD). Among them, the PVD includes a sputtering, a thermal deposition, and an electron beam deposition.

Since the sputtering may relatively easily obtain a thin film, regardless of the type of a substrate material, the sputtering is widely used in the manufacturing process of a display device. However, as display devices having a large area and high resolution are progressively required, the display devices may utilize more complicated thin films. In particular, film uniformity of the thin film formed on a processing object, such as a substrate, may be an important factor that influences the quality and performance of the product, and, as such, research have been conducted to improve thickness uniformity of the thin film formed.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a sputtering apparatus that may improve thickness uniformity of thin film formed and increase manufacturing efficiency.

Additional aspects will be set forth in the detailed description which follows, and, in part, will be apparent from the disclosure, or may be learned by practice of the inventive concept.

According to an exemplary embodiment of the present invention, a sputtering apparatus includes a chamber, a target section disposed in the chamber, and a stage facing the target section. The target section includes a first target having a first diameter and a second target having a second diameter different from the first diameter. The first target and the second target each extend in a longitudinal direction and have a cylindrical shape, and the first and second diameters are respectively measured along a cross-section of corresponding first and second targets taken along a direction perpendicular to the longitudinal direction.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of a sputtering apparatus according to an exemplary embodiment of the present invention.

FIG. 2 is a cross-sectional view of a portion of a sputtering apparatus according to an exemplary embodiment of the present invention.

FIG. 3 is a cross-sectional view of a portion of a sputtering apparatus according to an exemplary embodiment of the present invention.

FIG. 4 is a perspective view of a sputtering apparatus according to an exemplary embodiment of the present invention.

FIG. 5 is a cross-sectional view of a portion of a sputtering apparatus according to an exemplary embodiment of the present invention.

FIG. 6 is a schematic cross-sectional view illustrating an operation of a sputtering apparatus according to an exemplary embodiment of the present invention.

FIG. 7 is a schematic cross-sectional view of a sputtering apparatus according to an exemplary embodiment of the present invention.

FIG. 8 is a cross-sectional view of a portion of a sputtering apparatus according to an exemplary embodiment of the present invention.

FIG. 9 is a cross-sectional view of a portion of a sputtering apparatus according to an exemplary embodiment of the present invention.

FIG. 10 is a cross-sectional view of a portion of a sputtering apparatus according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

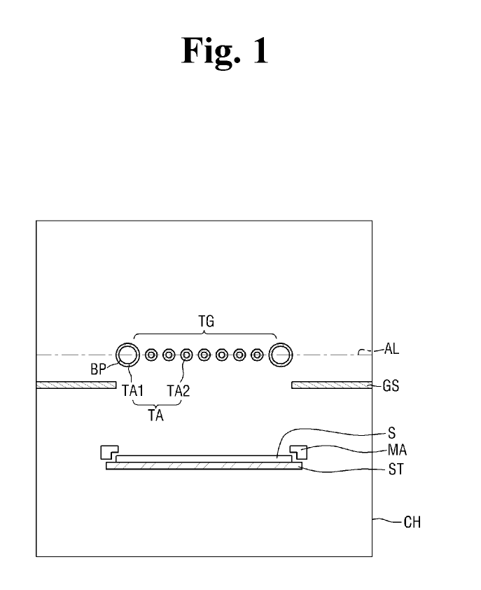

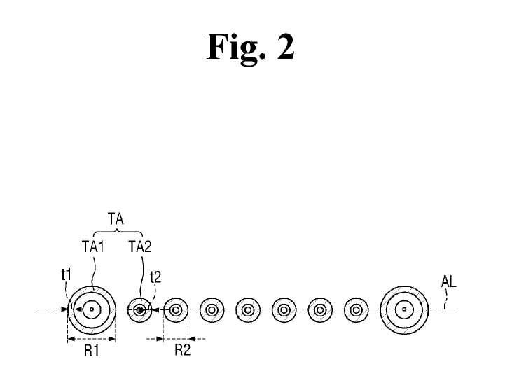

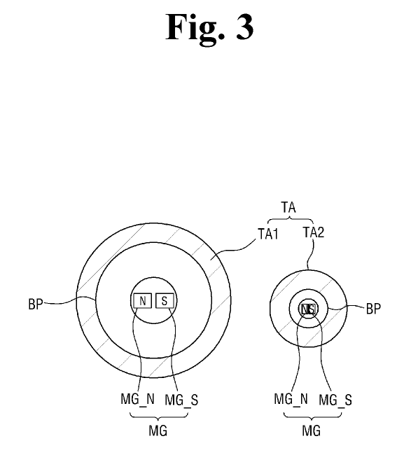

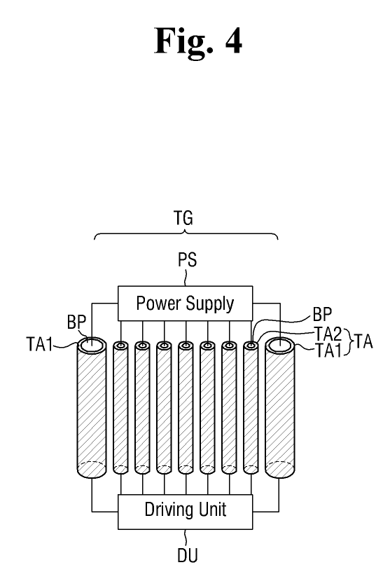

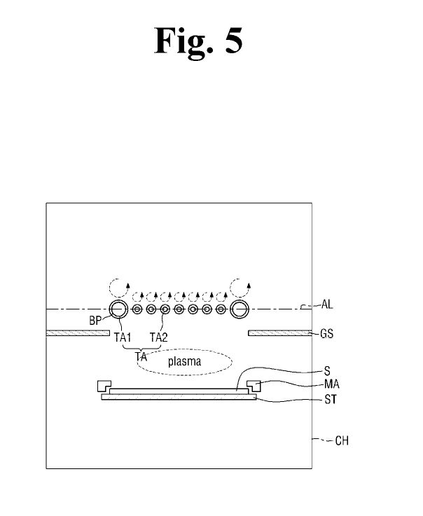

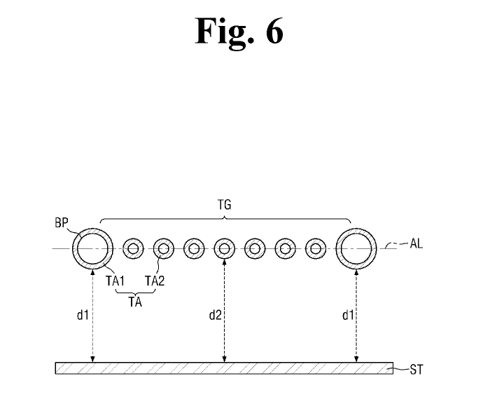

FIG. 1 is a schematic cross-sectional view of a sputtering apparatus according to an exemplary embodiment of the present invention. FIG. 2, FIG. 3, FIG. 4, and FIG. 5 are cross-sectional views of portion of a sputtering apparatus according to an exemplary embodiment of the present invention. FIG. 6 is a schematic cross-sectional view illustrating an operation of a sputtering apparatus according to an exemplary embodiment of the present invention.

Referring to FIGS. 1 to 6, a sputtering apparatus according to an exemplary embodiment of the invention includes a chamber CH and a target section TG disposed inside the chamber CH. The target section TG faces a stage ST and includes a first target TA1 and a second target TA2. The first target TA1 and the second target TA2 have a cylindrical shape that extends in the longitudinal direction.

The chamber CH may have an internal space, in which several constituent elements that will be further described below are disposed. The internal space of the chamber CH may be isolated from an external space of the chamber CH. That is, the internal space of the chamber CH may be a sealed space, such that the internal space and the external space of the chamber CH are separated from each other, thereby cutting off an air flow between the internal space and the external space.

The chamber CH may provide a deposition process space for guiding a formation of a film on a processing object, such as a substrate S. The chamber CH may have a suitable structure for the deposition process of the substrate S, e.g., a spherical structure or a hexagonal structure. The shape of the chamber CH may be varied

At least a portion of the chamber CH may include a metal material, such as stainless steel (SUS), aluminum (Al), titanium (Ti), or copper (Cu), or a material such as quartz glass. According to an exemplary embodiment of the present invention, the chamber CH may include ceramic.

When the deposition process for film formation is performed inside the chamber CH, the interior of the chamber CH may be in a vacuum state. The chamber CH may be connected to a gas supply unit (not illustrated) and may be supplied with gas for creating atmosphere necessary for the deposition process. For example, an atmosphere filled with an inert gas, such as argon (Ar), may be applied to the chamber CH.

The target section TG may be disposed inside the chamber CH. The target section TG may include a deposition material, which may be sputtered by plasma generated to perform the deposition process in the chamber CH. The target section TG may include at least one or more targets TA. Hereinafter, the target section TG will be described as to include multiple targets TA.

The target section TG may include a first target TA1 and a second target TA2. The first target TA1 and the second target TA2 have a cylindrical shape and may extend in the longitudinal direction. The first target TA1 and the second target TA2 may include a metal or the like to be deposited on the processing object, such as the substrate S. For example, the first target TA1 and the second target TA2 may include at least one of aluminum (Al), molybdenum (Mo), copper (Cu), gold (Au), and platinum (Pt), to form an electrode on the substrate S. It is noted that, however, the material of the target TA is not limited thereto. As another example, the target TA may include indium tin oxide (ITO), to form a transparent electrode.

The first target TA1 and the second target TA2 may include the same material or different materials from each other. When the first target TA1 and the second target TA2 include materials different from each other, the film formed on the substrate S by a sputtering process may be a mixed film that includes two or more materials. The target section TG will be described in more detail with reference to FIG. 2.

Referring to FIG. 2, the target section TG according to an exemplary embodiment of the present invention includes nine targets TA. It is noted that the number of targets TA may be varied.

The first target TA1 and the second target TA2 have a cylindrical shape and may be formed to extend in the longitudinal direction. The shapes of the cross-sections of the first target TA1 and the second target TA2 extending in the longitudinal direction, that is, the cross-sections taken along the direction perpendicular to the longitudinal direction, may be circular. The cross-section of the first target TA1 taken along the direction perpendicular to the longitudinal direction may have a first diameter R1. As used herein, the diameter is defined as a diameter of circular, i.e., a length of a straight line that connects two points that meet the outer circumferential surfaces of the first target TA1, when drawing a line passing through a center of a circular shape of the cross-section. The cross-section of the second target TA2 taken along the direction perpendicular to the longitudinal direction may have a second diameter R2. The first diameter R1 and the second diameter R2 may be different from each other. Specifically, the first diameter R1 may be relatively greater than the second diameter R2. When the first diameter R1 is greater than the second diameter R2, a distance between the processing object, such as a substrate S, and the target TA may change. More particularly, the distance between the first target TA1 and the substrate S may be less than the distance between the second target TA2 and the substrate S. The distance between the target TA and the substrate S may affect the thickness of the film formed on the substrate S, which will be described in more detail with reference to FIG. 6.

The thicknesses of the first target TA1 and the second target TA2 may be the same. Specifically, the first target TA1 has a first thickness t1, and the second target TA2 has a second thickness a t2, and the first thickness t1 and the second thickness t2 may be substantially the same. In this manner, a consumption rate of the deposition material of the first target TA1 and the second target TA2 may be the same, and as a result, an exchange cycle may become the same. As such, a separate pause to replace individual the first target TA1 and the second target TA2 may be avoided, since the replacement cycles of both targets TA1 and TA2 are the same, which may reduce the time required for replacement of the target TA.

As described above, the target section TG may include at least one or more targets TA. For example, the target section TG may include multiple first targets TA1 and multiple second targets TA2.

The targets TA may be aligned in a row. For example, when the cross-sections of the targets TA have a circular shape, a virtual alignment line AL connecting the center points of each target TA may be a straight line. When the centers of the targets TA are disposed on a straight virtual alignment line, the distance between the target TA and the stage ST may be different for each target TA. Specifically, the distance between the first target TA1 having the first diameter R1 and the stage ST may be less than the distance between the second target TA2 having the second diameter R2 and the stage ST, as the second diameter R2 is less than the first diameter R1. As described above, the distance between the target TA and the substrate S may affect the thickness of the film formed on the substrate S.

In the target section TG, the first target TA1 is disposed on the outermost (i.e., end) side of the target section TG, and the second target TA2 may be disposed adjacent to the first target TA1. More particularly, the first targets TA1 are disposed on both ends of the target section TG, and second targets TA2 may be disposed between the first targets TA1. As described above, the thickness of a film formed on the substrate S may be varied depending on the distance between the target TA and the processing object, such as a substrate S.

Forming a film on a frame portion (e.g., edge portion) of the substrate S may be relatively difficult in the deposition process. That is, due to the plasma concentration shortage in the frame portion of the substrate S or under the influence of a mask MA to be described below, a film formation on the frame portion may not be sufficient. Accordingly, the film formed on the frame portion may be thinner than the film formed on a central portion of the substrate S, which may deteriorate overall film thickness uniformity. According to exemplary embodiments of the present invention, when the first target TA1 having a relatively large first diameter R1 is disposed on one end side of the target section TG, to correspond to the frame portion of the substrate S, a film formation capability of the frame portion of the substrate S may be improved, which may improve uniformity of film thickness.

Referring to FIG. 3, a back plate BP may be disposed inside the target TA. The back plate BP has a cylindrical shape, and may be disposed in an internal space defined by the target TA. The back plate BP extends in the longitudinal direction. That is, the cross-section of the back plate BP taken along the direction perpendicular to the longitudinal direction may have a circular shape. Since the diameter of the cross-section of the back plate BP is less than the diameter of the cross-section of the target TA, the back plate BP may be disposed inside the target TA. In this case, the cross-section may have a concentric shape. In other words, the outer circumferential surface of the back plate BP and the inner surface of the target TA may be in direct contact with each other.

A magnet MG that forms a magnetic field may be disposed inside the back plate BP. The magnet MG may include alternately disposed magnets having polarities opposite to each other, so as to form a magnetic field on the surface of the target TA. In particular, the magnet MG may include an N-type magnet MG_N and an S-type magnet MG_S. The N-type magnet MG_N and the S-type magnet MG_S may be provided in plural, respectively. The magnet MG may have a bar shape extending in the longitudinal direction in the interior of the back plate BP. Alternatively, one of the N-type magnet MG_N and the S-type magnet MG_S may have a cylindrical shape, and the other thereof may be disposed inside the magnet having the cylindrical shape. The magnet MG may be designed to be movable within the space defined by the back plate BP. That is, the magnet MG may horizontally move or rotationally move. A sputtering apparatus may include a magnet driving unit (not illustrated) to drive the magnet MG.

Hereinafter, a driving method of the sputtering apparatus according to an exemplary embodiment of the present invention will be described with reference to FIGS. 4 and 5.

Referring to FIG. 4, the target section TG according to the present exemplary embodiment includes nine targets TA. It is noted that, however, the number of targets TA in the target section TG may be varied.

The back plate BP may be connected to a power supply unit PS that supplies radio frequency (RF) or direct current (DC) power supply. The back plate BP may receive the power supply from the power supply unit PS, and may serve as a cathode at the time of plasma discharge.

When the power is applied to the back plate BP, the plasma discharge may occur inside the plasma chamber CH, and an inert gas, such as argon (Ar), disposed inside the chamber CH may be ionized by the plasma discharge. When the ionized particles are accelerated toward the target TA to collide with the target TA, the metal atoms included in the target TA may be emitted from the target TA, and the emitted metal atoms may be deposited on the substrate S.

Referring to FIG. 5, the target TA according to an exemplary embodiment of the present invention may rotate in the sputtering apparatus. Specifically, the target TA may rotate about an axis extending in the longitudinal direction as a rotational axis. To this end, the targets TA may be connected to the target driving unit DU (not illustrated). The targets TA may be simultaneously controlled or may be individually controlled. For example, the targets TA may rotate at the same speed in the same direction. It is noted that, however, the targets TA may rotate in different directions or at different speeds from each other. For example, the first target TA1 and the second target TA2 may rotate in a clockwise direction or a counter-clockwise direction. Alternatively, the first target TA1 may rotate in the clockwise direction, and the second target TA2 may rotate in the counter-clockwise direction. The rotational speed or the rotational direction of the targets TA may be different between the first target TA1 disposed on one side and the first target TA1 disposed on the other side.

As the target TA rotates by the target drive DU, the back plate BP may rotate together or may be stopped. Alternatively, the back plate BP may be connected to a separate driving unit to independently move or to be stopped. In this manner, a consumption rate of the target material may be uniform throughout, as compared to a flat shaped plate target. Accordingly, usage time of the target TA according to the present exemplary embodiment may be relatively longer than the plate-shaped target that includes the same amount of target material, and improve the non-uniformity of film thickness formed on the substrate from uneven distribution of the target material.

Referring back to FIG. 1, the stage ST may be disposed to face the target section TG. The stage ST may support a processing object, such as the substrate S. The stage ST may further include a fixing member (not illustrated) that fixes the substrate S, so that the processing object such as a substrate S is seated. Further, the stage ST may move the substrate S to be suitable for the particular process. Specifically, the stage ST may move up and down, and may rotate to raise, lower, or turn the substrate S.

The substrate S may be disposed on the stage ST. For example, the substrate S may be a substrate that is used in an organic light emitting display device or a liquid crystal display device. As another example, the substrate may be a wafer that is used in semiconductor process.

A mask MA may be disposed on the stage ST. The mask MA may be disposed to be spaced apart from the stage ST and the substrate S disposed on the stage ST at a first distance. The mask MA may be disposed to surround the frame of the stage ST, to prevent the metal material of the target TA ejected by the argon (Ar) gas from being deposited inside the chamber CH. For example, the mask MA may have a rectangular shape having a cavity. That is, the mask MA may be in the form of a photo frame having an opening formed in a central portion. Therefore, the mask MA may at least partially expose an upper surface of the substrate S.

A ground shield GS may be disposed inside the chamber CH. The ground shield GS may be formed to extend from the inner surface of the chamber CH to the internal space of the chamber CH. The ground shield GS may be disposed on the side portion of the target section TG, and may block the magnetic field of the magnet MG. To this end, the ground shield GS may be disposed between the magnet MG and the stage ST. In addition, the ground shield GS may have a hollow rectangular shape in a planar view, which partially covers a portion of the frame of the mask MA or the substrate S. The ground shield GS may include a conductive metal, such as aluminum (Al). A ground potential may be applied to the ground shield GS. In this case, the ground shield GS may serve as an anode when discharge plasma into the chamber CH.

Hereinafter, effects of an sputtering apparatus according to an exemplary embodiment of the present invention will be described with reference to FIG. 6.

As described above, a distance (hereinafter, referred to as a first distance d1) between the first target TA1 and the stage ST may be less than a distance (hereinafter, referred to as a second distance d2) between the second target TA2 and the stage ST. Thus, when the processing object, such as the substrate S, is disposed on the stage ST, the distance between the first target TA1 and the substrate S may be less than the distance between the second target TA2 and the substrate S. As the distance between the processing object, such as a substrate S, and the target TA is closer, the thickness of the film formed on the substrate S may become relatively thicker. In general, the frame portion of the substrate S may have a plasma concentration lower than that of the central portion, or may have deposition characteristics inferior to that of the central part, due to the effects of the mask MA or the like. Accordingly, a film formed on the frame portion of the substrate S may be frequently formed thinner than the central part thereof. In the sputtering apparatus according to exemplary embodiments of the present invention, the first target TA1 having a relatively large diameter is disposed to correspond to the frame portion of the substrate S, which may improve the non-uniform thickness of the film formed on the substrate S between the frame portion and the central portion.

Hereinafter, a substrate processing apparatus according to an exemplary embodiment of the present invention will be described. For descriptive convenience, the same constituent elements are denoted by the same reference numerals, and repeated description thereof will be omitted.

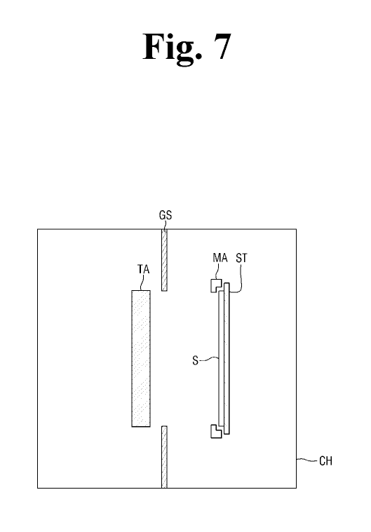

FIG. 7 is a schematic cross-sectional view of a sputtering apparatus according to an exemplary embodiment of the present invention.

Referring to FIG. 7, the target TA may extend in the longitudinal direction. As used herein, as compared to the sputtering apparatus of FIG. 1, the longitudinal direction according to the present exemplary embodiment may be a direction of gravity. For example, the target TA extending in the longitudinal direction may vertically stand in the chamber CH.

In this case, the stage ST facing the target section TG may vertically stand in the chamber CH. In other words, the upper surface of the stage ST may be in parallel with the longitudinal direction and may be perpendicular to the ground. When disposing the stage ST and the target TA in this way, the substrate S may also be disposed perpendicularly to the ground. In this manner, when performing the deposition process by disposing the substrate S perpendicularly to the ground, the uniformity of the film formed on the substrate S may be improved, as compared to the case of performing the deposition process by disposing the substrate S in parallel to the ground.

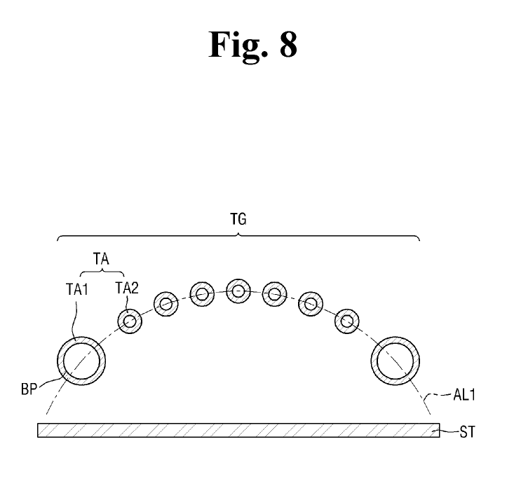

FIG. 8 is a cross-sectional view of a portion of a sputtering apparatus according to an exemplary embodiment of the present invention.

Referring to FIG. 8, a sputtering apparatus according to the present exemplary embodiment is different from the sputtering apparatus illustrated with reference to FIG. 1, in that a line connecting the center points of the targets TA has a parabolic shape.

The targets TA may be disposed along a virtual alignment line AL1, which substantially has a parabola shape and connects the center point of the target TA having a circular cross-section. In this case, a distance between the stage ST and each target TA may become greater as a target TA is disposed closer to a central portion of the target section TG. In other words, the distance between the first target TA1, which is disposed to correspond to the outside of the stage ST, and the stage ST is the shortest, and a distance between the second target TA2, which is disposed to correspond to a central portion of the stage ST, and the stage ST may be the greatest.

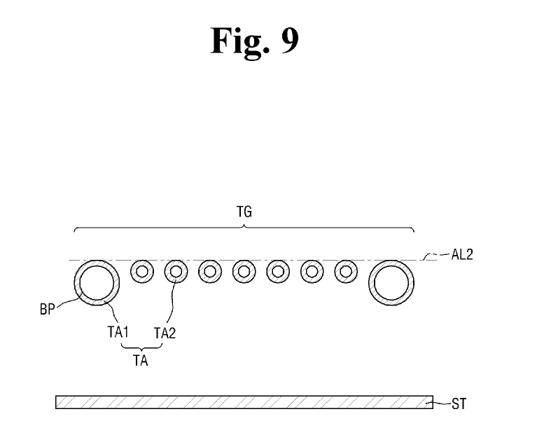

FIG. 9 is a cross-sectional view of a portion of a sputtering apparatus according to an exemplary embodiment of the present invention.

Referring to FIG. 9, a sputtering apparatus according to the present exemplary embodiment is different from the sputtering apparatus illustrated with reference to FIG. 1, in that the targets TA are disposed to tangentially contact a linear virtual alignment line AL2.

The targets TA may be in contact with the linear virtual alignment line AL2 at each point. That is, the targets TA may share the virtual alignment line AL2 as a tangent. In this manner, the distance between the first target TA1 and the stage ST may be less than the distance between the second target TA2 and the stage ST. Arrangements of the targets TA according to the present exemplary embodiment may compensate a decrease in the film formation characteristics in the frame portion of the substrate S, thereby improving a film thickness uniformity.

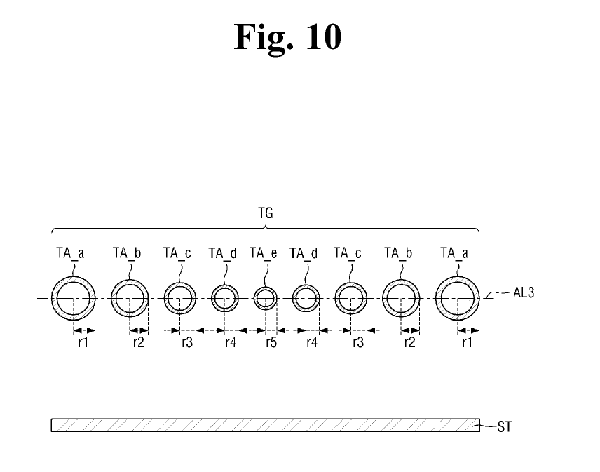

FIG. 10 is a cross-sectional view of a portion of a sputtering apparatus according to an exemplary embodiment of the present invention.

Referring to FIG. 10, a sputtering apparatus according to the present exemplary embodiment is a different from the sputtering apparatus illustrated with reference to FIG. 1, in that the diameter of each target TA gradually decreases as a target TA is disposed closer to a central portion of the target section TG.

The sputtering apparatus according to the present exemplary embodiment may include targets TA having different diameters from each other. For example, the sputtering apparatus may include a first target TA_a, second target TA_b, a third target TA_c, a fourth targets TA_d and a fifth target TA_e. The first target TA_a may have a first diameter r1, the second target TA_b may have a second diameter r2, the third target TA_c may have a third diameter r3, the fourth targets TA_d may have a fourth diameter r4, and the fifth target TA_e may have a fifth diameter r5. The first diameter r1 through the fifth diameter r5 may be different from each other. Specifically, the first diameter r1 is the largest, and the fifth diameter r5 may be the smallest. That is, the diameter may become sequentially smaller as from the first diameter r1 to the fifth diameter r5.

The diameter of each target TA may become smaller as a target TA is disposed closer to a center portion of the target section TG. For example, targets TA may be disposed in the order of the first target TA_a, the second target TA_b, the third target TA_c, the fourth target TA_d, the fifth target TA_e, the fourth TA_d, the third target TA_c, the second target TA_b and the first target TA_a. That is, the first target TA_a having the largest diameter may be located on both sides of the target section TG, and the target TA having the smaller diameter may be disposed as it goes inward. Thus, the fifth target TA_e having the smallest fifth diameter r5 may be disposed at a position corresponding to the central portion of the stage ST.

In this manner, the distance between the first target TA1 and the stage ST may be smaller than the distance between the second target TA_b through the fifth target TA_e and the stage ST. Accordingly, arrangements of the targets TA according to the present exemplary embodiment may compensate a decrease in the film formation characteristics in the frame portion of the substrate S, thereby improving a film thickness uniformity.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. A sputtering apparatus, comprising:
a chamber;
a target section disposed in the chamber, the target section comprising:
a first target having a first diameter; and
a second target having a second diameter different from the first diameter; and
a stage facing the target section,
wherein:
the first target and the second target each extend in a longitudinal direction and have a cylindrical shape; and
the first and second diameters are respectively measured along a cross-section of corresponding first and second targets taken along a direction perpendicular to the longitudinal direction.

2. The sputtering apparatus of claim 1, wherein the first diameter is greater than the second diameter.

3. The sputtering apparatus of claim 2, wherein:
first targets are respectively disposed on both ends of the target section; and
the second target is disposed between the first targets.

4. The sputtering apparatus of claim 3, further comprising:
a substrate disposed on the stage,
wherein the distance between the first target and the substrate is less than the distance between the second target and the substrate.

5. The sputtering apparatus of claim 2, wherein the distance between the first target and the stage is less than the distance between the second target and the stage.

6. The sputtering apparatus of claim 1, wherein the first target and the second target are disposed in plural.

7. The sputtering apparatus of claim 6, wherein the first targets and the second targets are arranged in a row.

8. The sputtering apparatus of claim 6, wherein a line that connects center points of the first targets and the second targets has a parabolic shape.

9. The sputtering apparatus of claim 1, wherein:
the target section further comprises a third target having a third diameter, the third target being disposed at a central portion of the target section; and
the second diameter is greater than the third diameter.

10. The sputtering apparatus of claim 1, wherein the thickness of the first target and the thickness of the second target are the same.

11. The sputtering apparatus of claim 1, further comprising a back plate disposed in the first target and the second target.

12. The sputtering apparatus of claim 11, further comprising magnets disposed inside the back plate.

13. The sputtering apparatus of claim 1, wherein the first target and the second target are configured to rotate about an axis extending in parallel to the longitudinal direction as a rotational axis.

14. The sputtering apparatus of claim 13, wherein the first target and the second target are configured to rotate in the same direction.

15. The sputtering apparatus of claim 13, wherein the first target and the second target are configured to rotate in different directions from each other.

16. The sputtering apparatus of claim 1, further comprising a mask disposed on the stage.

17. The sputtering apparatus of claim 1, further comprising a ground shield disposed on the stage and extending from an inner surface of the chamber to the interior of the chamber.

18. The sputtering apparatus of claim 1, wherein the first target and the second target comprise at least one of aluminum (Al), molybdenum (Mo), copper (Cu), gold (Au), and platinum (Pt).

19. The sputtering apparatus of claim 1, wherein the longitudinal direction corresponds to a direction of gravity.
